(19) United States
(12) Patent Application Publication
(10) Pub. No.: US 2014/0254617 A1
(43) Pub. Date: Sep. 11, 2014

(54) TUNABLE LASER DIODE DEVICE WITH AMZI-FP FILTER

(71) Applicant: Electronics and Telecommunications Research Institute, Daejeon (KR)

(72) Inventor: Kwang Ryong OH, Daejeon (KR)

(73) Assignee: Electronics and Telecommunications Research Institute, Daejeon (KR)

(21) Appl. No.: 14/168,583

(22) Filed: Jan. 30, 2014

(30) Foreign Application Priority Data
Mar. 6, 2013 (KR) 10-2013-0024065
Aug. 29, 2013 (KR) 10-2013-0103259

(51) Int. Cl. H01S 5/062

(52) U.S. Cl. CPC H01S 5/062
USPC 372/20

(57) ABSTRACT

The tunable light source structure proposed in the present invention has an advantage in that a limitation on a typical technology not simultaneously satisfying high-speed tuning and wide range tuning is overcome and thus it is possible to simultaneously satisfy high-speed tuning slower than or equal to several ns and 100 nm-level wide range tuning. Also, a driving method is simpler than that of a typical technology, a stable operation is possible, and it is possible to lower a manufacturing cost of all modules including a driving circuit. In implementing the SLD and the AMZI-FP that are key components of the tunable light source structure of the present invention, an Si or polymer optical waveguide as well as III-group to V-group materials (GaAs, InP and GaSb) may also be employed.

### CROSS-REFERENCE TO RELATED APPLICATIONS

This U.S. non-provisional patent application claims priority under 35 U.S.C. §119 of Korean Patent Application Nos. 10-2013-0024065, filed on Mar. 6, 2013, and 10-2013-0103259, filed on Aug. 29, 2013, the entire contents of which are hereby incorporated by reference.

### BACKGROUND

The present invention disclosed herein relates to a high speed tunable light source technology that is utilized for optical measurement and optical communication device.

Tunable light sources utilized for optical measurement and optical communication devices have a trade-off relation relative to a tunable range.

Such a characteristic is determined by an integrated filter. That is, the currently commercialized tunable light sources exhibit a wide tunable range characteristic and have an msec-level low speed switching characteristic. On the contrary, most of optical filters having an msec-level to nsec-level high speed switching characteristic exhibit a narrow tunable range characteristic in terms of operation principle. The results of such a characteristic limitation depend on the characteristic of the integrated filter.

A typical tunable filter is difficult to have a structure that may satisfy all of wide range tuning, successive tuning, and productivity as well as a high speed operation that does not exceed an msec level.

### SUMMARY

The present invention provides a tunable laser diode device that may overcome a high speed tunable limitation and simultaneously achieve wide range tuning and successive tuning.

The present invention also provides methods of manufacturing and operating a tunable filter of which a manufacturing process and a driving method are relatively simple.

Embodiments of the present invention provide tunable laser diode devices include an input unit; a first branch resonating unit connected to the input unit and having a first resonance length; a second branch resonating unit branched from the input unit together with the first branch resonating unit and having a second resonance length different from the first resonance length; and a filter including an output unit connected to the first branch resonating unit and the second branch resonating unit.

In other embodiments of the present invention, tunable laser diode devices include a laser diode unit comprising a grating waveguide filter; and an FP filter unit receiving single wavelength light from the laser diode unit through lens and having a branch resonating unit having different optical paths between an input unit and an output unit.

In other embodiments of the present invention, methods of operating an FP filter connected, through lens, to a laser diode unit including a grating waveguide filter include receiving a single wavelength light of the laser diode unit through an input unit through the lens; amplifying the received single wavelength light; simultaneously transmitting the amplified single wavelength light through a first branch resonating unit having a first resonance length and a second branch resonating unit having a second resonance length; selectively transmitting the single wavelength light by using interference between two FP modes when the two FP modes occur due to the simultaneous transmission.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 illustrates a structure of an asymmetric Mach Zehnder interferometer-Fabry Perot (AMZI-FP) filter according to an embodiment of the present invention;

FIG. 2 illustrates AMZI-FP filter transmission characteristic results according to FIG. 1;

FIG. 3 illustrates a structure of a semiconductor optical amplifier (SOA) integrated AMZI-FPP filter according to another embodiment of the present invention;

FIG. 4 illustrates AMZI-FP filter transmission tunable characteristic results according to FIG. 3;

FIG. 5 is a block diagram of a filter employing tunable laser diode according to the present invention;

FIG. 6 illustrates a reflective wave removing principle of the tunable laser diode according to FIG. 5; and

FIG. 7 illustrates mode dependent tunable output waveforms according to FIG. 5.

### DETAILED DESCRIPTION OF PREFERRED EMBODIMENTS

The above-described objects, other objects, characteristics, and advantages of the present invention will be easily understood through the following exemplary embodiments related to the accompanying drawings. However, the present invention is not limited to the following embodiments but may be embodied in other forms. Rather, these embodiments are provided so that this disclosure will be thorough and complete, and will fully convey the scope of the present invention to a person skilled in the art.

In the specification, when some elements or lines are referred to as being connected to a target element block, it should be understood that the former can be directly connected to the latter, or indirectly connected to the latter via another element.

Moreover, the same or like reference numerals in each of the drawings represent the same or like components if possible. In some drawings, the connection of elements and lines is just represented to effectively explain technical content and may further include other elements or circuit blocks.

An embodiment described and exemplified herein may include a complementary embodiment thereof, and the details of the basic operations and physical characteristics of a laser diode device will not be described in detail in order not to obscure the subject matter of the present invention

Without intents other than an intent to provide more thorough understandings on the present invention, an example of filters according to typical technologies that are being used as components of a tunable light source will be described before describing the present invention.

A Fabry-Perot (FP) filter that is one of typical representative tunable filters takes a form of a linear resonator including two mirrors.

Resonance occurs at wavelengths of certain intervals due to optical coherence that appears while incident light is successively reflected from the two mirrors or some of the incident light is transmitted. Consequently, the FP filter has a periodic transmission characteristic according to a wavelength.

The tuning of such an FP filter may be made by adjusting the gap between the two mirrors or change a refractive index of a material, and related several implementation techniques are proposed and used.

If the two minors configuring the resonator of the FP filter are attached to a piezoelectric transducer (PZT) and then a voltage is applied thereto, the gap between the two minors varies by the inflation of the PZT.

Since the tuning is implemented through such a mechanical variation, there is a limitation in that an operating speed has an msec level. Freedericksz transition appears in which liquid crystal molecules are rearranged if an electric field having certain intensity is applied to liquid crystal. Thus, a refractive index of the liquid crystal varies. Such an FP filter is a filter that is implemented by changing the refractive index of the liquid crystal in the resonator. Therefore, a liquid crystal FP filter is limited to dozens of msec to hundreds of msec in polarization operation speed and thus a filter character appears as a problem.

A micro machined FP filter adjusts the gap between minors of the FP filter by using a semiconductor that shows a micro variation by electrostatic force or heat. The micro machined FP filter may be aimed at enhancement in integrated characteristic and stability based on a semiconductor device technology but a limitation on a speed of msec or dozens of ms still remains.

Mode coupling indicates that an energy exchange between modes occurs by perturbation at an optical waveguide. As a tunable filter using the mode coupling, there are polarization mode conversion and space mode conversion filters.

These also have a limitation in that an operating speed is dozens of msec to hundreds of msec or a tunable range is very narrow.

A tunable filter using a Mach-Zehnder (MZ) interferometer has a structure in which a phase modulator is arranged at an optical waveguide through which light passes, between two 3 dB combiners. In the case of the tunable filter using the MZ interferometer, since LiNbO3 is used as a phase modulating device and thus a high speed operation of dozens of nsec is possible, but it has limitations in that a structure is complex and manufacturing is difficult.

A technique is also known in which tension or heat is applied to an optical fiber diffraction grating of which a refractive index is changed periodically along the optical fiber, to change the period of a grating. Even in this case, the PZT is used for a mechanical variation but an operating speed still has an msec level due to a limitation on a heat reaction speed.

Distributed feedback (DFB)/distributed Bragg reflector (DBR) and grating assisted co-directional coupler (GACC) filters of a semiconductor waveguide type similar to a semiconductor laser diode may change wavelengths by hundreds of thousands of nm by injecting currents. However, they overall have a limited utilization range due to a narrow variation, discontinuity in variation, and instability.

A structure to make an optical waveguide as a ring type and to excite or output to a directional combiner causes resonance periodically if the unique optical path of the ring itself becomes an integer multiple of a wavelength. In this case, a phase modulator is arranged in a resonator to electrically make a wavelength variation by an external signal. Here, a fast operation of dozens of msec is possible according to a material to be used.

A semiconductor laser in which three (or two) Y branches are integrated uses a Veriner effect that occurs due to the micro interval difference of three (or two) FP resonating modes formed in the whole resonator. Such a technology may is advantageous in terms of tunable region expansion and make a high speed variation by current injection. However, since there is a limitation on selectivity in that the difference between the filter transmission of a main mode causing lasing and a side mode is not great is carried out, the performance of a side mode suppression ratio (SMSR) is not good.

As mentioned above, in the case of a typical tunable filter, a structure has not been proposed which may all satisfy wide range tuning, successive tuning, and productivity as well as a high speed operation that does not exceed an msec level.

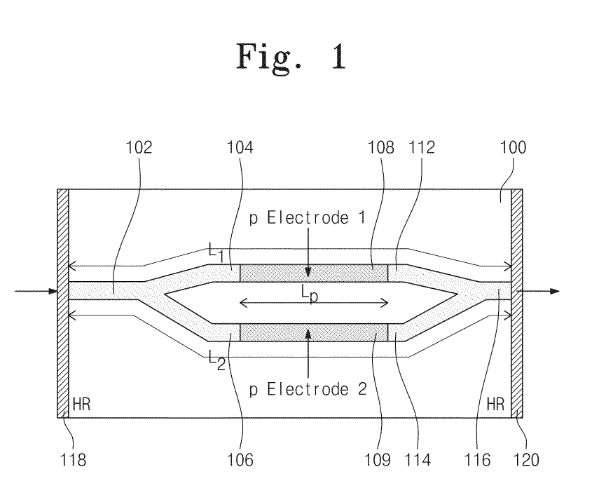

The present invention provides a structure shown in FIG. 1 as an example of a structure of a filter for overcoming the above-described limitations.

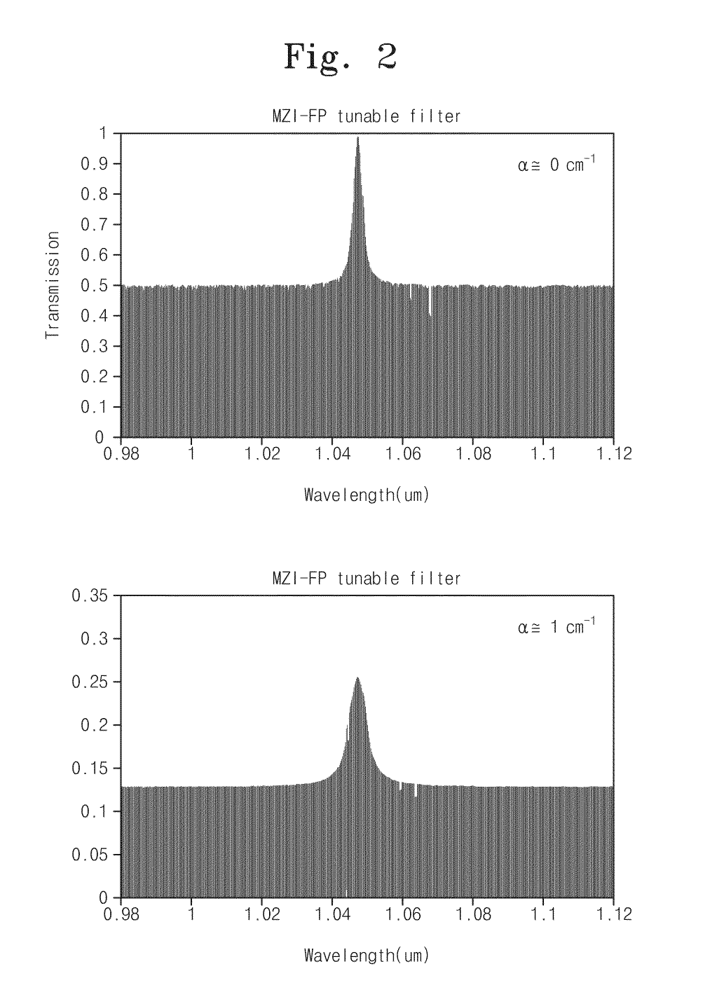

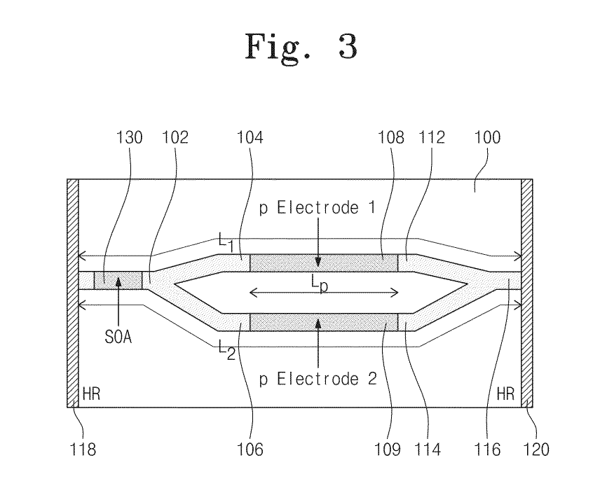

FIG. 1 illustrates a structure of an asymmetric Mach Zehnder interferometer-Fabry Perot (AMZI-FP) filter according to an embodiment of the present invention. Also, FIG. 2 illustrates AMZI-FP filter transmission characteristic results according to FIG. 1. In addition, FIG. 3 illustrates a structure of a semiconductor optical amplifier (SOA) integrated AMZI-FPP filter according to another embodiment of the present invention.

The structure of FIG. 1 shows an AMZI-FP optical filter chip as one of key components of the present invention.

Referring to FIG. 1, a filter of a tunable laser diode device includes an input unit 102, an output unit 116, a first branch resonating unit 104, and a second branch resonating unit 106.

The first branch resonating unit 104 is connected to the input unit 102 and has a first resonance length.

The second branch resonating unit 106 is branched from the input unit 102 together with the first branch resonating unit, and has a second resonance length that is different from the first resonance length.

The output unit 116 is connected to the first branch resonating unit 104 and the second branch resonating unit 106 and outputs light.

The filter structure of FIG. 1 is a waveguide structure of a Mach-Zehnder interferometer (MZI) type having a difference in length of two arms. Generally, in the case of MZI, an anti-reflective thin film is formed on an input and an output and thus interference occurs due to the difference between two paths. However, in the embodiment of the present invention, a high reflective (HR) thin film is formed on the input and the output to generate two FP modes. The interference of the FP modes is used in the embodiment of the present invention.

A tunable filter using a Vernier effect may be implemented at two FP waveguides which have resonance lengths L₁ and L₂, respectively and different (free spectral ranges) FSRs. In this case, a maximum tunable range is

[D1/1=n_{eff0}(L₁/(L₂−L₁)]

and is multiplied by a lever effect coefficient L₁/(L₂−L₁).

That is, as the difference in length of two FP resonators decreases, tunable displacement increases. Also, the transmission characteristic of the MZI-FP optical filter may be represented by Equation 2 below.

$${T}_{MZI \text{-} FP} = \frac{\frac{1}{2} {( 1 - R )}^{2} {e}^{- a {L}_{1}}}{{( 1 - {Re}^{- α {L}_{1}} )}^{2} + 4 {Re}^{- α {L}_{1}} sin ( 2 π ( {n}_{eff 0} ( {L}_{1} - {L}_{p} ) + {n}_{neff 1} {L}_{p} ) / λ )} + \frac{\frac{1}{2} {( 1 - R )}^{2} {e}^{- α {L}_{2}}}{{( 1 - {Re}^{- α {L}_{2}} )}^{2} + 4 {Re}^{- α {L}_{2}} sin ( 2 π ( {n}_{eff 0} ( {L}_{2} - {L}_{p} ) + {n}_{eff 2} {L}_{p} ) / λ )}$$

In Equation 2 above, R is a reflectivity of input and output sections, Lₚ is a changed length of an effective refractive index of a waveguide according to an applied voltage or current, a is a loss factor, n_{eff0} is a fixed effective refractive index of a fixed waveguide without an electrode, and n_{eff1} and n_{eff2} are effective refractive indexes of a waveguide under an electrode changed by applying a current or a voltage.

For example, n_{eff0}=3.32, L₁=500 um, L₂=501 um, and R=95%, and if calculating transmission characteristics by using Equation 2 when a=0 cm⁻¹ and a=1 cm⁻¹, FIG. 2 may be obtained.

In FIG. 2, the horizontal axis represents a wavelength and the vertical axis represents transmission.

The upper graph of FIG. 2 represents when a=0 cm⁻¹ and the lower graph of FIG. 2 represents when a=1 cm⁻¹.

FIG. 2 is a result obtained by decreasing, by 0.001, a refractive index of an electrode waveguide part of a lower waveguide in order to adjust a central wavelength region where two FP modes match.

As could be seen from a result shown in the lower graph of FIG. 2, the transmission of a central wavelength may drastically decrease by slight waveguide loss.

In manufacturing III-group to V-group compound waveguides, an optical amplifier 130 may be inserted into an input as shown in FIG. 3. The reason for this is to consider that it is not easy to obtain a waveguide having an extremely low loss and to compensate for a loss of the whole waveguide.

As compared to the structure of FIG. 1, FIG. 3 further includes an optical amplifier 130 performing optical amplification. The optical amplifier 130 is installed at the input unit 102. Under the structure of FIG. 3, if the whole waveguide loss is adjusted to be close to 0, the transmission of a central wavelength may be close to 1.

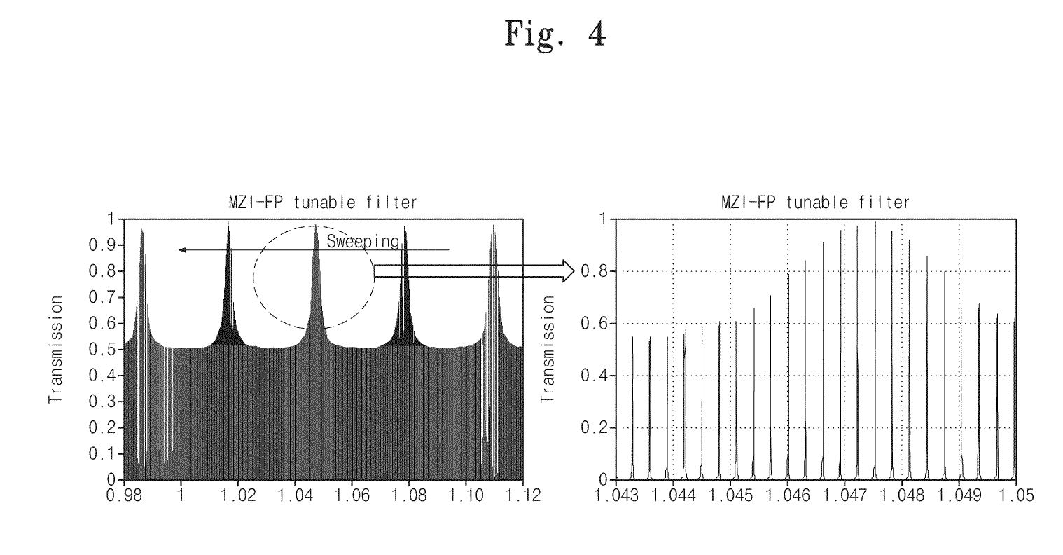

FIG. 4 illustrates AMZI-FP filter transmission tunable characteristic results according to FIG. 3.

FIG. 4 shows a calculation result that a central wavelength moves by distance equal to or longer 100 nm when a refractive index of a waveguide is changed by 0.002 on the assumption that a=0 cm⁻¹. If expanding the transmission characteristic of a central wavelength part, it is checked that full width at half maximum (FWHM) relative to maxim transmission is 5nm and an FP mode interval is about 0.31 nm, as shown in FIG. 4. In FIG. 4, the horizontal axis represents a wavelength and the vertical axis represents transmission.

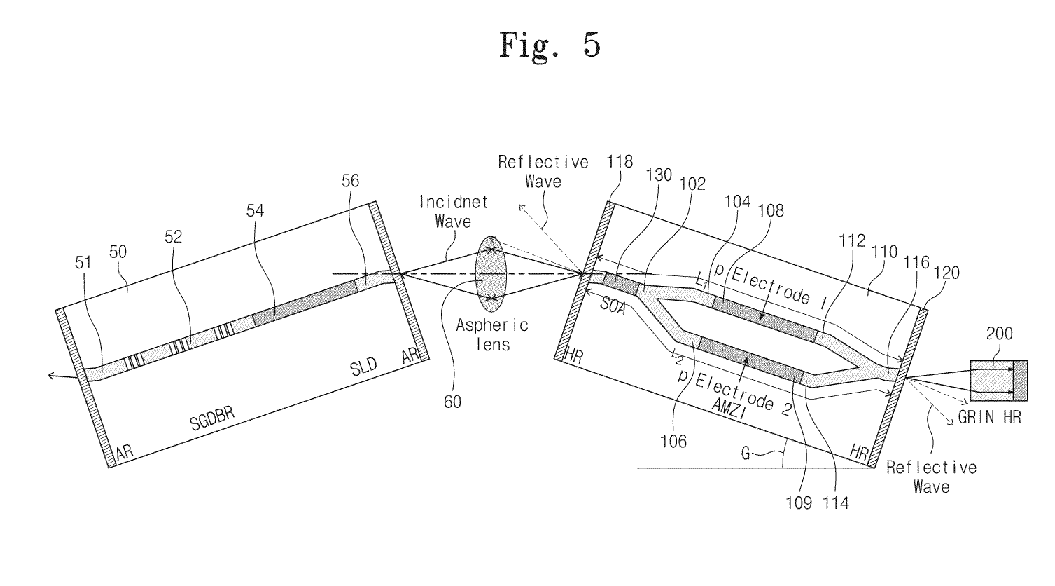

In the case of the AMZI-FP filter according to the embodiment of the present invention, the FWHM of a central wavelength is determined based on the reflectivity of the high-reflection thin film of an input and an output and several FP modes are included in the FWHM. Therefore, a secondary filter may be further needed for the selection of a single wavelength. That is, if an sampled grating distributed Bragg reflector (SGDBR) (or a super structure grating (SSG)) grating waveguide filter having an FSR corresponding to the FWHM relative to the maximum transmission as shown in FIG. 5 is overlap, it is possible to select one of the transmission modes of a central wavelength region of an MZI-FP filter. Thus, a single mode operation is possible.

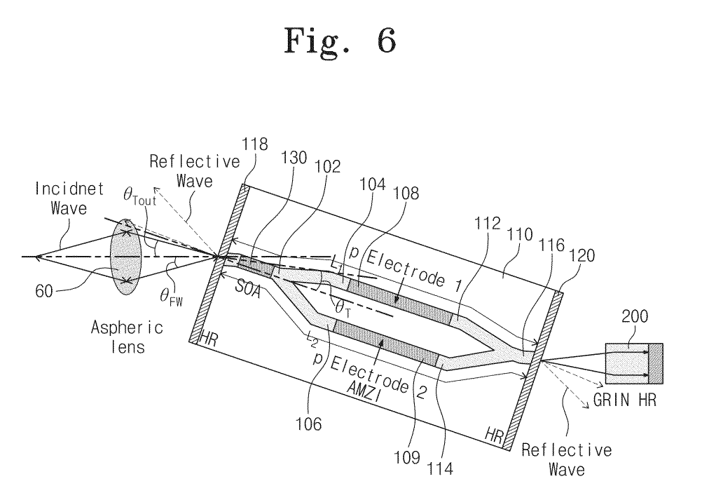

FIG. 5 is a block diagram of a filter-employing tunable laser diode according to the present invention, and FIG. 6 illustrates a reflective wave removing principle of the tunable laser diode according to FIG. 5.

Referring to FIG. 5, a laser diode unit 50 that includes a grating waveguide filter, and an FP filter unit 110 that receives single wavelength light of the laser diode unit 50 through lens 60 and has a branch resonating unit having different optical paths between an input unit and an output unit are shown.

Consequently, the whole structure of FIG. 5 represents the connection between the laser diode unit 50 having an SGDBR (or SSG) grating waveguide filter and the AMZI-FP filter 110 for single wavelength selection, and the FP filter unit 110 including a semiconductor optical amplifier (SOA) for optical amplification.

The laser diode unit 50 may be a super-luminescent laser diode (SLD).

The laser diode unit 50 may be implemented by using a material, such as III-group to V-group compound (InP, GaAs and GaSb), Si and polymer, capable of applying a current or voltage to a core layer, in order to function as a tunable laser. The SLD functions as a diffractive grating filter for a sampled grating distributed Bragg reflector (SGDBR) or super structure grating (SSG) that has a narrow line width and shows a reflective spectrum characteristic of an FSR of dozens of nm

Also, The FP filter unit 110 is manufactured by integrating two FP waveguides having different FSRs as an MZI-type single chip. Thus, an AMZI-FP optical filter chip is obtained which represents wide range tuning using a Vernier effect.

In FIG. 5, the AMZI-FP filter 110 employs a tilt input and output waveguide structure unlike FIG. 3. If a straight-line waveguide as shown in FIG. 1 or 3 is employed which has no tilt and vertically meets a section, an incident wave coming from the SLD 50 may be reflected from the section of an AMZI-FP filter input and returned immediately to the SLD 50. If a resonance mode according to the return is formed, lasing occurs. Also, if a straight-line output waveguide is used when returning light 60 passing through the AMZI-FP filter 110 through lens, an undesired new mode may be formed.

Thus, if the input and output waveguide of the MZI-FP filter 110 has a tilt corresponding to a certain angle G as shown in FIG. 5, a reflective wave is not returned through lens. That is, the reflective wave is scattered.

As a tilt waveguide having an angle of 7° is generally used when designing and manufacturing an anti-reflective waveguide of III-group to V-group compound, reflectivity decreases when the tilt of a waveguide increases.

That is, in the embodiment of the present invention, light coming from the outside may have a high-reflection characteristic that a reflective wave is scattered and not returned and the reflectivity of an input and an output is 90% or higher for a filter characteristic of a narrow FWHM. To this end, an optimized design is needed for the tile of a waveguide.

As shown in FIG. 6, the optical axis of the AMZI-FP chip 110, the optical axis and angle θ_{Tout} of an incident beam and a waveguide tilt angle θ_{T} need to be first aligned according to Snell's law, sin θ_{Tout}=n_{eff0}×sin θ_{T} for effective optical coupling. Also, in order to minimize the return of light reflected from an AMZI-FP section to the SLD 50, the optical axis of the AMZI-FP chip and the optical axis and angle θ_{Tout} of an incident beam need to be set to be better than the FWHM of an SLD radiation angle θ_{FW}. Consequently, the waveguide tilt angle θ_{T} determined according to the Snell's law may be set to be within a range that the reflectivity of a section is equal to or greater than 90%.

For example, when an effective waveguide refractive index n_{eff0} is 3.32 and the FWHM of the SLD radiation angle θ_{FW} is 5°, a waveguide tile θ_{T} needs to be equal to or greater than 1.5° to minimize the return of a reflective wave and may be less than or equal to 2° on the condition that 90% reflectivity is maintained. That is, the waveguide tilt angle is set to 1.5°□<θ_{T}□<2°□, it is possible to suppress lasing due to the minimum return to the SLD and maintain a filter characteristic due to the high reflectivity of an MZI-FP filter section.

The single mode selection and tuning processes of the structure according to the present invention are discussed in the following.

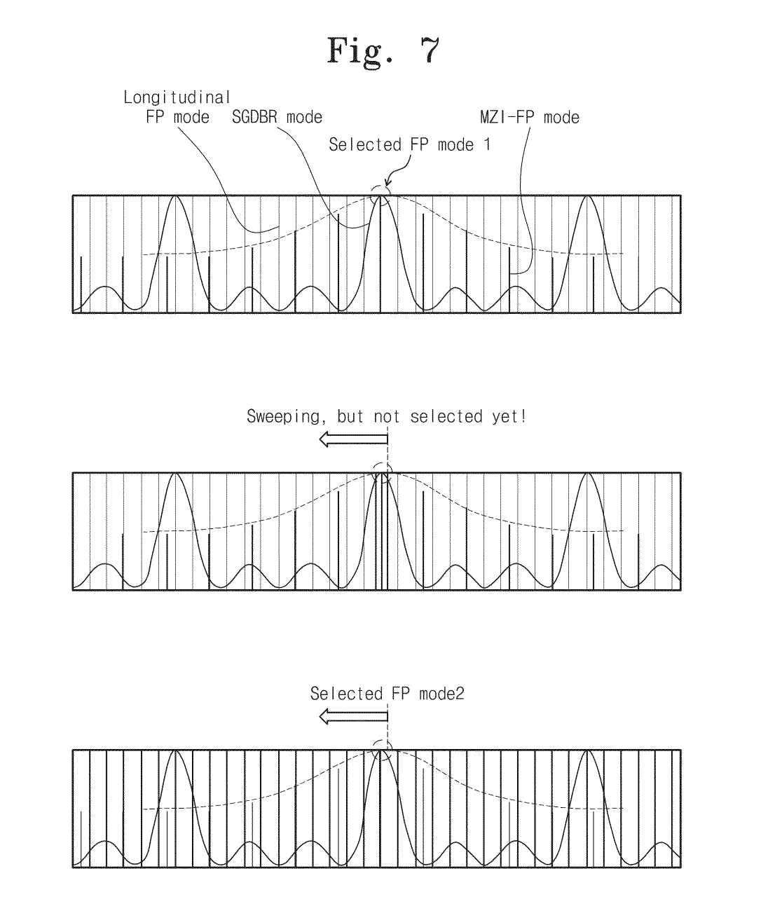

FIG. 7 illustrates mode dependent tunable output waveforms according to FIG. 5.

As shown in FIG. 7, in the present structure, three modes may be formed, such as the AMZI-FP resonance mode, the SGDBR (or SSG) mode, and the longitudinal FP mode of the whole resonator that are mentioned above. The longitudinal FP mode of the whole resonator may be selected to overlap with several things within the FWHM of the maximum transmission of the AMZI-FP and only one of these is selected by using the SGDBR mode. That is, in selection and tuning, the AMZI-FP mode successively selects the longitudinal FP mode relative to the whole tunable region with a refractive index change of a waveguide by an applied current or voltage.

The SGDBR mode repetitively moves by its FSR and selects one longitudinal FP mode overlapping with the AMZI-FP mode to be able to successively select a single longitudinal FP mode. Consequently, if the loss of the whole resonator is compensated for the selected single mode through the light amplifier, it is possible to implement a laser in which a single longitudinal FP mode successively tunes.

The change reaction time of the refractive index of III-group to V-group compound may shorten to be shorter than or equal to several ns depending on the life time of a carrier by current injection. That is, it is possible to implement a filter that enables 100 nm or more wide range tuning and a high speed operation slower than or equal to several ns.

The tunable light source structure proposed in the present invention has an advantage in that a limitation on a typical technology not simultaneously satisfying high-speed tuning and wide range tuning is overcome and thus it is possible to simultaneously satisfy high-speed tuning slower than or equal to several ns and 100 nm-level wide range tuning.

Also, a driving method is simpler than that of a typical technology, a stable operation is possible, and it is possible to lower a manufacturing cost of all modules including a driving circuit.

In implementing the SLD and the AMZI-FP that are key components of the tunable light source structure of the present invention, an Si or polymer optical waveguide as well as III-group to V-group materials (GaAs, InP and GaSb) may also be employed.

Hitherto, the best mode was disclosed in the drawings and specification. While specific terms were used, they were not used to limit the meaning or the scope of the present invention described in Claims, but merely used to explain the present invention. Accordingly, a person having ordinary skill in the art will understand from the above that various modifications and other equivalent embodiments are also possible.

For example, it is possible to change details of a tunable laser diode device by altering, adding or removing the structure or configuration of drawings without departing the technical spirit of the present invention in other cases. Also, although the concept of the present invention is mainly described on the tunable laser diode device, the present invention is not limited thereto but may be applied to other light source systems.

What is claimed is:

1. A tunable laser diode device comprising:
an input unit;
a first branch resonating unit connected to the input unit and having a first resonance length;
a second branch resonating unit branched from the input unit together with the first branch resonating unit and having a second resonance length different from the first resonance length; and
a filter comprising an output unit connected to the first branch resonating unit and the second branch resonating unit.

2. The tunable laser diode device of claim 1, wherein the first resonance length of the first branch resonating unit and the second resonance length of the second branch resonating unit decrease as tunable displacement increases.

3. The tunable laser diode device of claim 1, wherein the filter is a Mach-Zehnder interferometer (MZI)-type Fabry Perot (FP) filter.

4. The tunable laser diode device of claim 1, further comprising an optical amplifier performing optical amplification at the input unit.

5. The tunable laser diode device of claim 1, further comprising a laser diode unit comprising a grating waveguide filter at the front end of the input unit.

6. The tunable laser diode device of claim 1, wherein the output unit and the output unit comprise high reflective films.

7. A tunable laser diode device comprising a filter, the filter comprising:
an input unit;
an output unit;
an optical amplifier arranged at the input unit and performing optical amplification;
a first branch resonating unit connected to the input unit and having a first resonance length;
a second branch resonating unit connected as a path different from a path of the first branch resonating unit between the input unit and the output unit and having a second resonance length different from the first resonance length.

8. The tunable laser diode device of claim 7, wherein the first resonance length of the first branch resonating unit is shorter than the second resonance length of the second branch resonating unit.

9. The tunable laser diode device of claim 8, wherein the input unit and the output unit have high reflective films to use interference between two FP modes.

10. The tunable laser diode device claim 9, wherein the filter is an asymmetric Mach Zehnder interferometer (AMZI)-type filter.

11. The tunable laser diode device of claim 10, wherein the filter further comprises a laser diode unit comprising a grating waveguide filter, at a front end of the filter.

12. A tunable laser diode device comprising:
a laser diode unit comprising a grating waveguide filter; and
an FP filter unit receiving single wavelength light from the laser diode unit through lens and having a branch resonating unit having different optical paths between an input unit and an output unit.

13. The tunable laser diode device of claim 12, wherein the grating waveguide filter comprises a sampled grating distributed Bragg reflector (SGDBR).

14. The tunable laser diode device of claim 12, wherein the grating waveguide filter comprises a super structure grating (SSG).

15. The tunable laser diode device of claim 12, wherein the FP filter unit is an MZI-type FP filter.

16. The tunable laser diode device of claim 12, wherein the FP filter unit comprises:
a first branch resonating unit connected to the input unit and having a first resonance length;
a second branch resonating unit connected as a path different from a path of the first branch resonating unit between the input unit and the output unit and having a second resonance length different form the first resonance length.

17. The tunable laser diode device of claim 16, wherein the FP filter unit further comprises an optical amplifier arranged at the input unit and performing optical amplification.

18. The tunable laser diode device of claim 16, wherein the FP filter unit is arranged at an angle relative to a central horizontal line of the lens to remove a reflective wave.

19. The tunable laser diode device of claim 16, wherein at the FP filter unit, the first resonance length is shorter than the second resonance length.

20. A method of operating an FP filter connected, through lens, to a laser diode unit comprising a grating waveguide filter, the method comprising:
receiving a single wavelength light of the laser diode unit through an input unit through the lens;
amplifying the received single wavelength light;
simultaneously transmitting the amplified single wavelength light through a first branch resonating unit having a first resonance length and a second branch resonating unit having a second resonance length; and
selectively transmitting the single wavelength light by using interference between two FP modes when the two FP modes occur due to the simultaneous transmission.
